(19) United States
(12) Patent Application Publication
(10) Pub. No.: US 2025/0055497 A1
(43) Pub. Date: Feb. 13, 2025

(54) TRANSCEIVER CAPACITANCE REDUCTION

(71) Applicant: Micron Technology, Inc., Boise, ID (US)

(72) Inventors: Robert Wimmer, Hastings, MN (US); Jeremy Kuehlwein, Woodbury, MN (US)

(21) Appl. No.: 18/770,390

(22) Filed: Jul. 11, 2024

Related U.S. Application Data
(60) Provisional application No. 63/531,941, filed on Aug. 10, 2023.

(51) Int. Cl. H04B 1/40; H01L 27/02

(52) U.S. Cl. CPC H04B 1/40; H01L 27/0266; H01L 27/0288

(57) ABSTRACT

Systems, methods and apparatus are provided for transceiver capacitance reduction. An example apparatus can comprise a first signal driver of a transceiver, a second signal driver of the transceiver, and an input/output (I/O) pad coupled to the first and second signal drivers. The apparatus can further comprise a resistor divider of a plurality of resistor dividers coupled to the first signal driver. The resistor divider, when enabled, can reduce capacitance of the first signal driver and maintain the reduced capacitance while the second signal driver is actively driving a signal.

### PRIORITY INFORMATION

This application claims the benefit of U.S. Provisional Application No. 63/531,941, filed on Aug. 10, 2023, the contents of which are incorporated herein by reference.

### TECHNICAL FIELD

The present disclosure relates generally to electronic apparatuses and methods, and more particularly, to apparatuses and methods for transceiver capacitance reduction.

### BACKGROUND

Electronic apparatuses (e.g., devices and systems) include various integrated circuits (ICs) (e.g., chips) such as microprocessors, controllers, memory devices, field programmable gate arrays (FPGAs), application specific integrated circuits (ASICs), and system-on-a-chip (SoC) integrated circuits, among various other types of digital and/or analog integrated circuits. Various ICs include input/output (I/O) circuitry that can provide an interface between ICs (e.g., to send and/or receive signals). Accordingly, I/O circuitry often includes a physical pin through which signals (e.g., data) can be communicated (e.g., transmitted and/or received). As such, in some instances, the term “I/O pin” can be used to refer to the physical pin as well as additional I/O circuitry (e.g., transmit driver circuitry, receiver driver circuitry, etc.) coupled thereto. I/O circuits configured to both transmit and receive signals are referred to as bidirectional I/Os, and I/O circuits configured to only transmit signals or only receive signals are referred to as unidirectional I/Os.

### BRIEF DESCRIPTION OF THE DRAWINGS

FIG. 1 is a block diagram of an apparatus in the form of a portion of an electronic system for reducing transceiver capacitance in accordance with a number of embodiments of the present disclosure.

FIG. 2 is a block diagram illustrating an example I/O component for reducing transceiver capacitance in accordance with a number of embodiments of the present disclosure.

FIG. 3 is a block diagram illustrating another example I/O component for reducing transceiver capacitance in accordance with a number of embodiments of the present disclosure.

FIG. 4 is a flow diagram of a method for reducing transceiver capacitance in accordance with a number of embodiments of the present disclosure.

### DETAILED DESCRIPTION

Systems, apparatuses, and methods related to reducing transceiver capacitance are described. In a bidirectional I/O circuit, transceivers (e.g., transmitter, receiver, etc.) are attached to the same I/O pad. In some examples, the transmitter can contribute a greater amount of capacitance to the I/O pad capacitance than the receiver, which can significantly degrade the receiver's performance. For example, a transmitter using current mode logic (CML) with a large current load can result in greater capacitance contribution from the transmitter than the receiver.

In some approaches, in order to reduce pin capacitance as much as possible, extensive layout optimization can be carried out. Tcoils can also be added to the I/O pad to differentiate capacitance from the pad and the signal drivers and to strengthen signal integrity. However, these approaches do not aid reducing undesirable impact on one signal driver (e.g., the transmitter of a transmitter/receiver pair, which can be referred to as a transceiver) from capacitance of a different signal driver (e.g., the receiver of the transmitter/receiver pair).

Aspects of the present disclosure address the above and other challenges associated with reducing signal driver capacitance. In embodiments of the present disclosure, undesirable impact on one signal driver that would have been caused from capacitance of a different signal driver can be reduced; thereby, improving performance of the one signal driver. Signal drivers can be coupled to resistor dividers within the I/O circuit. A gate voltage of the signal driver can be reduced by resistor dividers in order to reduce the capacitance of the signal driver. Reduced capacitance of one signal driver can strengthen the performance of another signal driver. For example, the capacitance of a first signal driver can be reduced while a second signal driver, which is coupled to the first signal driver, is actively driving a signal. A digital core, connected to the I/O circuit can send a timed signal to alert the I/O circuit that the gate voltage of the resistor divider can be reduced.

As used herein, the singular forms “a”, “an”, and “the” include singular and plural referents unless the content clearly dictates otherwise. Furthermore, the word “may” is used throughout this application in a permissive sense (i.e., having the potential to, being able to), not in a mandatory sense (i.e., must). The term “include,” and derivations thereof, mean “including, but not limited to.” The term “coupled” means directly or indirectly connected. Further, as used herein, the term “decrease”, “reduce”, and/or “lower” (or the like) can be interchangeably used to indicate the same meaning.

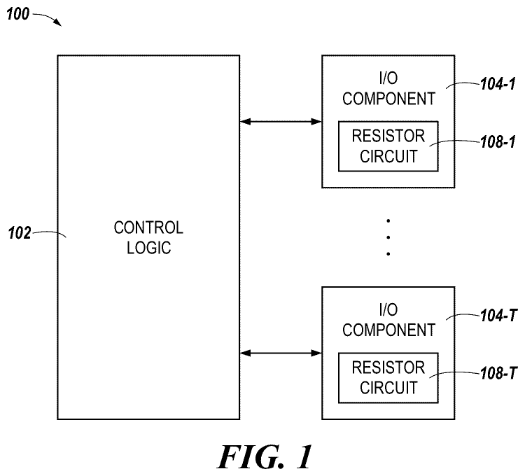

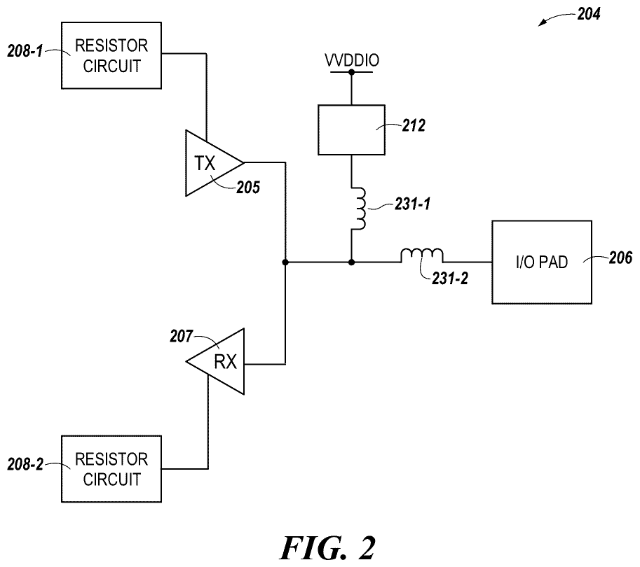

The figures herein follow a numbering convention in which the first digit or digits correspond to the drawing figure number and the remaining digits identify an element or component in the drawing. Similar elements or components between different figures may be identified by the use of similar digits. For example, 104 may reference element “04” in FIG. 1, and a similar element may be referenced as 204 in FIG. 2.

Analogous elements within a Figure may be referenced with a hyphen and extra numeral or letter. See, for example, elements 104-1, . . . , 104-T in FIG. 1. Such analogous elements may be generally referenced without the hyphen and extra numeral or letter. For example, elements 104-1, . . . , 104-T can be collectively referenced as 104. As used herein, the designators “T”, particularly with respect to reference numerals in the drawings, indicates that a number of the particular feature so designated can be included. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate certain embodiments of the present invention and should not be taken in a limiting sense.

FIG. 1 is a block diagram of an apparatus 100 in the form of an electronic system for reducing transceiver capacitance in accordance with a number of embodiments of the present disclosure. Electronic systems can include memory devices and solid-state drives (SSDs). Memory devices are typically provided as internal, semiconductor, integrated circuits in computers or other electronic systems. There are many different types of memory including volatile and non-volatile memory. Volatile memory can require power to maintain its data (e.g., host data, error data, etc.) and includes random access memory (RAM), dynamic random access memory (DRAM), static random access memory (SRAM), synchronous dynamic random access memory (SDRAM), and thyristor random access memory (TRAM), among others. Non-volatile memory can provide persistent data by retaining stored data when not powered and can include NAND flash memory, NOR flash memory, ferroelectric random access memory (FeRAM), and resistance variable memory such as phase change random access memory (PCRAM), resistive random access memory (RRAM), and magnetoresistive random access memory (MRAM), such as spin torque transfer random access memory (STT RAM), among others.

Memory devices may be coupled to a host (e.g., a host computing device) to store data, commands, and/or instructions for use by the host while the computer or electronic system is operating. For example, data, commands, and/or instructions can be transferred between the host and the memory device(s) during operation of a computing or other electronic system. A controller (such as control logic 102) may be used to manage the transfer of data, commands, and/or instructions between the host and the memory devices.

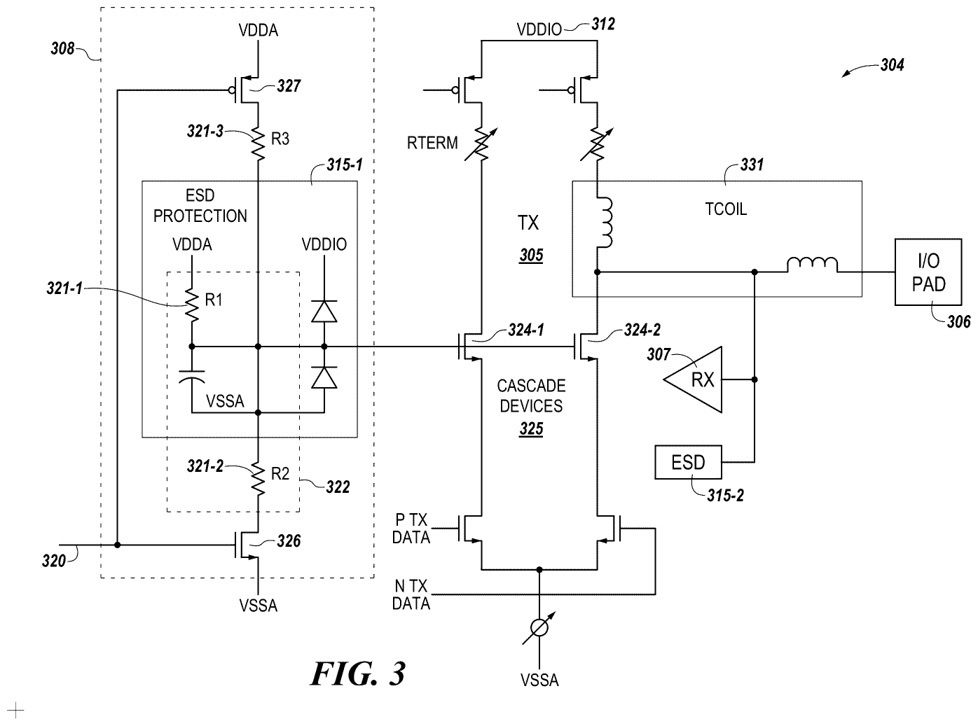

The apparatus 100 can include control logic 102 and input/output (I/O) components 104-1, . . . , 104-T (collectively referred to as “I/Os 104”). The control logic 102 can be coupled to I/Os 104. As used herein, a “control logic” refers to a reusable unit of processor, and/or co-processors that receive instructions and perform tasks or actions based on the received instructions. The control logic 102 can include special purpose circuitry in the form of an ASIC, FPGA, state machine, and/or other logic circuitry or software and/or firmware to facilitate operations described herein. For example, the control logic 102 can send a timed signal (e.g., timed signal that can be received via a timed signal line 320 in FIG. 3) to each I/O component 104 to alert a reduction of the capacitance level of signal drivers within the I/Os 104. Also, the control logic 102 can include special purpose circuitry in the form of an ASIC, FPGA, state machine, and/or other logic circuitry or software and/or firmware that can allow the control logic 102 to communicate with the I/Os 104. The control logic 102 can be coupled to I/Os 104 to send and/or receive a signal from the I/Os 104.

As further illustrated in FIG. 3, I/Os 104 can include one or more signal lines, signal drivers (e.g., transmitter, receiver, etc.), I/O pads, etc. that can receive an external signal (e.g., signal received from an external device, such as control logic 102), receive an internal signal (e.g., signal received from an I/O pad within the I/Os 104), and/or transmit the received signal (e.g., to the control logic 102 and/or the I/O pad). As used herein, a signal driver can be a transmitter (e.g., transmitter 305 illustrated in FIG. 3) or a receiver (e.g., receiver 307 illustrated in FIG. 3).

Although embodiments are not so limited, I/Os 104 can form various buses (e.g., data buses, address buses, command buses, etc.) and can be placed in various locations of the electronic system. For example, I/O components can be placed among peripheral devices (e.g., sensors, actuators, displays, etc.), a host (e.g., a desktop computer, laptop computer, network server, mobile device, or such computing device that includes a memory and a processing device), storage system (e.g., including memory dice) etc. of the electronic system.

In some embodiments, one or more of I/Os 104 can be part of (e.g., form) a “port”, which can be a physical port, such as serial advanced technology attachment (SATA) ports, peripheral component interconnect express (PCIe) ports, universal serial bus (USB) ports, Fibre Channel ports, Serial Attached SCSI (SAS) ports, Small Computer System Interface (SCSI) ports, a dual in-line memory module (DIMM) ports, an NVM Express (NVMe) ports, Open NAND Flash Interface (ONFI) ports, etc. Further, in some embodiments, I/Os 104 can be (e.g., integrated) part of the controller 102 instead of being separate components independently of the controller 102.

Also, as further illustrated in FIGS. 2-3, the I/Os 104 can include various circuitry to facilitate reducing transceiver capacitance. For example, the I/Os 104 can include resistor circuits 108-1, . . . , 108-T (collectively referred to as “resistor circuits 108”). The resistor circuits 108 can include a plurality of resistors, which can form one or more resistor dividers to reduce the capacitance of the specific signal driver connected to the resistor divider. As further illustrated in FIGS. 2-3, each I/O component 104 can include one or more switches that can be used to selectively couple the resistors to form the resistor divider. A switch can be placed in the resistor dividers to control capacitance to the signal driver connected to the resistor divider. The signal drivers can be controlled by the output voltage of the resistor dividers.

FIG. 2 is a block diagram illustrating an example I/O component 204 (alternatively referred to as “I/O 204”) for reducing transceiver capacitance in accordance with a number of embodiments of the present disclosure. I/O 204 and resistor circuit 208 can be respectively analogous to I/O 104 and resistor circuit 108 illustrated in FIG. 1.

An I/O 204 can operate with a power supplied via a power supply voltage 212 (shown as VVDDIO in FIG. 2). As illustrated in FIG. 2, the I/O component 204 includes a first signal driver of a transceiver (e.g., a transmitter 205 shown as “TX” in FIG. 2), a second signal driver of the transceiver (e.g., a receiver 207 shown as “RX” in FIG. 2). As used herein, the term ‘transceiver’ generally refers to an input signal driver (e.g., a receiver) or an output signal driver (e.g., a transmitter) of an I/O component. Further, as used herein, the term “transmitter” can be alternatively referred to as “transmit driver”, “output signal driver”, etc. Further, the term “receiver” can be alternatively referred to as “receiver driver”, “input signal driver”, etc. As illustrated in FIG. 2, the transmitter 205 as an output signal driver is operable to drive a signal (e.g., received externally) to an I/O pad (e.g., I/O pad 206) and while the receiver 207 as an input signal driver is operable to drive a signal received from the I/O pad, such as I/O pad 206. Tcoils 231-1 and 231-2 (collectively referred to as Tcoil node 231) can be connected to the I/O pad 206 to differentiate capacitance from the I/O pad 206 and the signal drivers 205, 207 and to strengthen signal integrity.

Signal drivers of an I/O can be respectively coupled to and/or include a resistor circuit, such as resistor circuits 208-1 and 208-2. For example, as illustrated in FIG. 2, a transmitter 205 is coupled to the resistor circuit 208-1 and a receiver 207 is coupled to the resistor circuit 208-2.

Each resistor circuit 208 can include resistors (e.g., resistors 321-1, 321-2, and 321-3 illustrated in FIG. 3) that can form at least one resistor divider (e.g., resistor divider 322 illustrated in FIG. 3). When enabled, these resistors can operate to reduce capacitance of a respective signal driver, which can improve performance of the other signal driver while the respective signal driver is actively driving a signal. For example, at least while the receiver 207 is actively driving the signal, the resistor circuit 208-1 can operate to reduce capacitance of the transmitter 205 so as to prevent interference with performance of the receiver 207 that would have occurred from the capacitance (e.g., parasitic capacitance) of the transmitter 205 that is sufficiently high to cause such. Vice versa, at least while the transmitter 205 is actively driving the signal, the resistor circuit 208-2 can operate to reduce capacitance of the receiver 207 so as to prevent interference with performance of the transmitter 205 that would have occurred from the capacitance (e.g., parasitic capacitance) of the receiver 207 that is sufficiently high to cause such.

The voltage level of one signal driver 205 or 207 that has been reduced and/or maintained at a reduced level to effect a reduced capacitance can be restored back to the increased level, which can cause an increase of the capacitance of the signal driver 205 or 207. For example, the resistor circuit 208-1 can operate to increase the voltage level (that has been maintained at the reduced level while the receiver 207 was actively driving a signal) associated with the transmitter 205 to allow the transmitter 205 to actively drive a signal with the increased voltage level. Vice versa, the resistor circuit 208-2 can operate to increase the voltage level (that has been maintained at the reduced level while the transmitter 205 was actively driving a signal) associated with the receiver 207 to allow the receiver 207 to actively drive a signal with the increased voltage level.

When to decrease (e.g., reduce) capacitance of a respective signal driver 205, 207 can be controlled by a timed signal sent from a control logic (e.g., the control logic 102 in FIG. 2). For example, the control logic can send a first timed signal (e.g., with a first voltage level) to enable resistors (e.g., of a respective resistor circuit 208-1 or 208-2 and that forms a resistor divider) to reduce the capacitance of the respective signal driver 205, 207. Subsequently, the control logic can send a second timed signal (e.g., with a second voltage level) to enable resistors (of a respective resistor circuit 208-1 or 208-2 and that include one or more resistors that do forms the resistor divider) to increase the voltage level of the respective signal driver 205, 207 (e.g., at a faster rate). These timed signals can be interchangeably sent to an I/O 204 in a manner that allows for quick switching (alternatively referred to as “turnaround time”) between different sets of resistors and activation of different signal drivers 205, 207 without the delay.

In some embodiments, the control logic can entirely disable the resistor circuits 208-1, 208-2 to cause an I/O 204 to operate without additional resistors (e.g., resistors 321-2 and 321-3 illustrated in FIG. 3) of the resistor circuits 208-1, 208-2 being selectively enabled or disabled. Therefore, in this example, an I/O 204 can operate without further adjusting voltage levels of the signal drivers 205, 207 via the respective resistor circuit 208-1, 208-2. Resistor circuits 208-1, 208-2 can be entirely disabled during operation of an I/O 204 in the event that operating an I/O 204 with functionalities provided by resistor circuits 208-1, 208-2 does not allow the quick switching between activation of different signal drivers 205, 207 without substantial delay.

FIG. 3 is a block diagram illustrating another example I/O component 304 for reducing transceiver capacitance in accordance with a number of embodiments of the present disclosure. Transmitter 305, receiver 307, I/O pad 306, resistor circuit 308, Tcoil node 331 (shown as “TCOIL”), and VVDDIO 312 can be respectively analogous to transmitter 205, receiver 207, I/O pad 206, resistor circuit 208, Tcoil node 231, and VVDDIO 212 illustrated in FIG. 2. As used herein, both transmitter and receiver can be referred to as “signal driver” while the term “first signal driver” can refer to transmitter, while the term “second signal driver” can refer to receiver (or vice versa).

As compared to the transmitter 205 illustrated in FIG. 2, the transmitter 305 is illustrated in further details in FIG. 3. For example, as illustrated in FIG. 3, the transmitter 305 includes a termination circuit (shown as “RTERM” in FIG. 3), a cascode device 325, Complementary Metal-Oxide-Semiconductor (CMOS)-based transmission gate switches respectively to receive complementary data signals (shown as “P TX Data” and “N TX Data” in FIG. 3). In some embodiments, the transmitter 305 can be a current mode logic (CML) buffer. Resistor circuit 308 is also illustrated in further detail in FIG. 3. For example, as illustrated in FIG. 3, the resistor circuit 308 includes resistors 321-2, 321-3, resistor divider 322, CMOS switches 326 and 327, and at least a portion of ESD circuit 315-1, such as resistor 321-1.

As illustrated in FIG. 3, transmitter 305 and receiver 307 are respectively coupled to Electrostatic Discharge (ESD) circuits 315-1 and 315-2. Although embodiments are not so limited, an ESD circuit can include ESD protection diodes, transient voltage suppression (TSV) diodes, etc. as shown in relation to the ESD circuit 315-1. The ESD protection circuits 315-1 and 315-2 provide protection respectively to signal drivers 305, 307 from damages that would occur from ESD events.

The I/O component 304 further includes resistors 321-2 and 321-3 that are respectively connected to the transmitter 305 either in series or in parallel with a resistor 321-1 of the ESD protection circuit 315-2. The resistors 312-2 and 321-3 can be selectively enabled along with the resistor 321-1 responsive to a timed signal that can be sent from a control logic (e.g., the control logic 102 in FIG. 1) coupled to I/O component 304 through timed signal line 320. Alternatively speaking, the control logic can determine when to send the timed signal to selectively enable resistors 321; thereby, selectively increasing or decreasing the voltage level of the transmitter 305.

The resistors 321-2 and/or 321-3 (collectively referred to as resistors 321) can be selectively enabled to increase and/or decrease the voltage level of the transmitter 305. The resistors 321-2 and/or 321-3 can be enabled to switch voltage levels from an operating level (e.g., at which the respective signal driver is desired to actively drive a signal) to a reduced voltage level. The enabling of the resistors 321-2 and/or 321-3 (while resistor 321-1 remains enabled) can reduce the time it takes for the voltage level to switch between the operating level and the reduced level (e.g., RC time constant). Some of the resistors 321 can form a resistor divider, in which constituent resistors are connected in series. For example, resistors 321-1 and 321-2 that are connected to (e.g., the cascode gate 324-1 of) the transmitter 305 in series can form a resistor divider 322. As used herein, “enabling” one or more resistors and/or resistor dividers refers to allowing a current to flow through the “enabled” resistors and/or resistor dividers.

When enabled, the resistor divider 322 can cause a level of capacitance associated with the transmitter 305 to be reduced and maintained at a particular level (e.g., a reduced level). For example, the resistor divider 322, when enabled, can reduce a voltage level of the cascode gate 324-1 of the transmitter 305, which further reduces the capacitance level of the transmitter 305 that has been maintained at a higher level. The reduced capacitance level is maintained at least while the resistor divider 322 is being enabled.

As illustrated in FIG. 3, an extra resistor 321-3 is connected (e.g., to the transmitter 305, such as cascode device 325) in parallel with resistor 321-1. An extra resistor 321-3 can be enabled along with resistor 321-1 to reduce the RC time constant associated with increasing a voltage level across the cascode device 325, such as cascode gate 324-1 (e.g., to VDDA). Accordingly, the extra resistor 321-3 enabled along with the first resistor 321-1 can increase the voltage level across the cascode device 325 at a faster rate than a rate at which the voltage level would have been increased using the resistor 321-1 alone, which can improve the turnaround time. The resistors 321-2 and 321-3 can be enabled in an alternative manner such that resistors 321-2 and 321-3 are enabled one at a time. As such, the resistor 321-2 can be enabled to decrease the voltage level of the transmitter 305 while the resistor 321-3 can be enabled to increase the voltage level of the transmitter 305. The resistor 321-1 can be kept enabled while either the second resistor 321-2 or the resistor 32103 are enabled.

As illustrated in FIG. 3, the resistor divider 322 is coupled to cascode device 325 within transmitter 305. As used herein, the term “cascode device” refers to an amplifier that is used to enhance the performance of the transmitter 305. The cascode device can be a metal-oxide-semiconductor (MOS) device. In this illustration, the cascode device 325 includes a cascode gate 324-1 and a common source transistor 324-2 that are arranged in a way that enhances the performance of the transmitter 305. The resistor 321 can interact with the cascode device 325, through cascode gate 324-1, to increase or decrease the gate voltage (e.g., a voltage across the cascode gate 324-1) for the transmitter 305.

In one example, decreasing the gate voltage of the cascode device 325 can further “turn off” the cascode device 325 (e.g., to put the cascode device 325 into a high impedance state). In another example, increasing the gate voltage of the cascode device 325 can further “turn on” the cascode device 325 to enhance the performance of the transmitter 305. The gate voltage of the transmitter 305 can be set (e.g., determined) by respective values of the resistors 321-1 and 321-2 of the resistor divider 322.

The resistors 321 can be selectively enabled depending on whether the transmitter 305 or the receiver 307 is actively driving and/or desired to be actively driving a signal (e.g., a signal indicative of data, address, command, etc.). For example, the resistor divider 322 (e.g., including first and second resistors 321-1 and 321-2) can be enabled (e.g., to reduce capacitance of the cascode device 325) while the receiver 307 is actively driving a signal. Alternatively, the third resistor 321-3 can be enabled (e.g., to increase the voltage level of the cascode device 325) while the transmitter 305 is actively driving a signal. In both situations, the first resistor 321-1 is constantly on to enable both the first signal driver and the second signal driver.

A switch 326 can operate to enable/disable resistor 321-2 within the resistor divider 322, while a switch 327 can operate to enable/disable resistor 321-3. For example, a particular timed signal (e.g., having a first voltage level and/or a first polarity) from the control logic 102 can selectively activate the CMOS switch 326 (while deactivating the switch 327) to enable the resistor divider 322. For example, a particular timed signal (e.g., having a second voltage level and/or a second polarity) from the control logic 102 can selectively activate the switch 327 (while deactivating the switch 326) to enable resistor 321-3. Although embodiments are not so limited, the switch 326 and/or 327 can be a Complementary Metal-Oxide-Semiconductor (CMOS)-based transmission gate switch. One of the switches 326, 327 can be a P-type metal-oxide-semiconductor logic (PMOS) switch while the other switch 326, 327 can be an N-channel metal-oxide semiconductor (NMOS) switch. For example, the switch 327 can be a PMOS switch, while the switch 326 can be a NMOS switch.

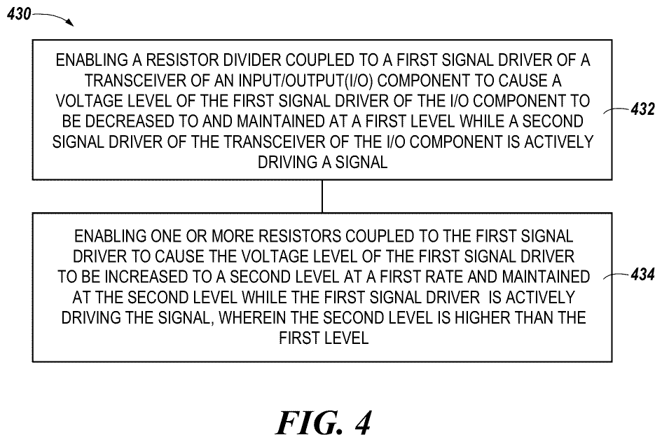

FIG. 4 is a flow diagram 430 of a method for reducing transceiver capacitance in accordance with a number of embodiments of the present disclosure. The method as illustrated by the flow diagram 430 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At 432, a resistor divider (e.g., the resistor divide 322) coupled to a first signal driver (e.g., the transmitter 205, 305 or receiver 207, 307 alternatively) of an input/output (I/O) component (e.g., I/O components 104, 204, and/or 304 illustrated in FIGS. 1-3, respectively) can be enabled to cause a voltage level of the first signal driver of a transceiver of the I/O component to be decreased to and maintained at a first level while a second signal driver of the transceiver (e.g., the receiver 207, 307 or transmitter 205, 305 alternatively) of the I/O component is actively driving a signal (e.g., a signal indicative of data, which is alternatively referred to as “data signal”). As illustrated in association with FIG. 3, decreasing the voltage level of the first signal driver 205, 305 can be analogous to decreasing a voltage level of (e.g., a voltage across) the cascode gate 324-1 of the transmitter 305. In some embodiments, the resistor divider 322 coupled to the first signal driver 205, 305 can be enabled by activating a first complementary metal-oxide semiconductor (CMOS) switch 326 coupled to the resistor divider 322. Further, one or more resistors 321-1, 321-3 coupled to the first signal driver 305 can be disabled, while the second signal driver 307 is actively driving a signal.

At 434, one or more resistors (e.g., resistors 321-1 and 321-3) coupled to the first signal driver 205, 305 can be enabled to cause the voltage level of the first signal driver 205, 305 to be increased to a second level at a first rate and maintained at the second level while the first signal driver 205, 305 is actively driving the signal. As illustrated in association with FIG. 3, increasing the voltage level of the first signal driver 205, 305 can be analogous to increasing a voltage level of (e.g., a voltage across) the cascode gate 324-1 of the transmitter 305. The second level can be higher than the first level. In some embodiments, the one or more resistors 321-1, 321-3 coupled to the first signal driver 205, 305 can be enabled by activating a second CMOS switch 327 coupled to the resistor divider 322. Further, the resistor divider 322 coupled to the first signal driver 205, 305 can be disabled, while the first signal driver 205, 305 is actively driving a signal.

In some embodiments, the resistor divider 322 can include a first resistor (e.g., resistor 321-1) and a second resistor (e.g., resistor 321-2). Further, one or more resistors can include the first resistor 321-1 and a third resistor (e.g., resistor 321-3). In this example, while the third resistor 321-3 is maintained to be disabled, the first resistor 321-1 can be enabled to cause a voltage level of the first signal driver 205, 305 to be increased to the second level at a second rate and maintained at the second level while the first signal driver 205, 305 is actively driving the signal, wherein the second rate is faster than the first rate.

Although specific embodiments have been illustrated and described herein, those of ordinary skill in the art will appreciate that an arrangement calculated to achieve the same results can be substituted for the specific embodiments shown. This disclosure is intended to cover adaptations or variations of one or more embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the one or more embodiments of the present disclosure includes other applications in which the above structures and processes are used. Therefore, the scope of one or more embodiments of the present disclosure should be determined with reference to the appended claims, along with the full range of equivalents to which such claims are entitled.

In the foregoing Detailed Description, some features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. An apparatus, comprising:
a first signal driver of a transceiver;
a second signal driver of the transceiver;
an input/output (I/O) pad coupled to the first and second signal drivers; and
a resistor divider coupled to the first signal driver, the resistor divider, when enabled, operable to reduce capacitance of the first signal driver and maintain the reduced capacitance while the second signal driver is actively driving a signal.

2. The apparatus of claim 1, wherein:
the resistor divider comprises a first resistor and a second resistor; and
the apparatus further comprises a third resistor coupled in parallel with the first resistor.

3. The apparatus of claim 2, wherein the first resistor and the second resistor are enabled in parallel to reduce capacitance of the first signal driver.

4. The apparatus of claim 2, wherein the first resistor is enabled along with the third resistor to reduce a RC time constant associated with increasing a voltage level of the first signal driver.

5. The apparatus of claim 2, wherein the second and third resistors are coupled to different complementary metal-oxide semiconductor (CMOS) switches to be enabled one at a time.

6. The apparatus of claim 5, wherein:
the second resistor is coupled to an N-channel metal-oxide semiconductor (NMOS) switch; and
the third resistor is coupled to the second CMOS switch corresponds to a P-type metal-oxide-semiconductor logic (PMOS) switch.

7. The apparatus of claim 2, wherein:
the apparatus further comprises an electrostatic discharge (ESD) circuit, in which the first resistor is located; and
the second and third resistors are coupled to the ESD circuit.

8. The apparatus of claim 1, wherein the first signal driver is a transmitter and the second signal driver is a receiver.

9. The apparatus of claim 1, wherein the resistor divider is operable to reduce a gate voltage of a cascode device of the first signal driver at least while the second signal driver is actively driving the signal.

10. A system, comprising:
an input/output (I/O) component comprising:
a first signal driver of a transceiver;
a second signal driver of the transceiver; and
one or more resistors coupled to the first signal driver; and
a control logic coupled to the I/O component, the control logic configured to:
send a first timed signal to the I/O component to enable a first portion of the one or more resistors to cause a voltage level associated with the first transceiver to be maintained at a first level, while the second transceiver is actively driving a signal; and
send a second timed signal to the I/O component to enable a second portion of the one or more resistors to cause a voltage level associated with the first transceiver to be maintained at a second level, while the second transceiver is actively driving the signal, wherein the second level is higher than the first level.

11. The system of claim 10, wherein:
the first portion of the one or more resistors further comprises first and second resistors corresponding to a resistor divider, the resistor divider operable to decrease a voltage level of the first signal driver to the first level; and
the second portion of the one or more resistors further comprises the first resistor and a third resistor, the third resistor operable along with the first resistor to increase a voltage level of the first signal driver to the second level at a first rate.

12. The system of claim 11, wherein the control logic is configured to send a disable signal to:
maintain, while a voltage level associated with the first signal driver is decreased to and maintained at a third level, the second resistor disabled, wherein the third level is higher than the first level; and
maintain, while a voltage level associated with the first signal driver is increased to and maintained at the second level, the third resistor disabled to increase a voltage level of the first signal driver to the second level at a second rate, wherein the first rate is faster than the second rate.

13. The system of claim 11, wherein the first and second resistors are connected to the first signal driver in series.

14. The system of claim 11, wherein the first and third resistors are connected to the first signal driver in parallel.

15. The system of claim 11, wherein the control logic is configured to:
send the first timed signal to activate a first complementary metal-oxide semiconductor (CMOS) switch coupled to the resistor divider to further enable the resistor divider; and
send the second timed signal to activate a second CMOS switch coupled to the third resistor to further enable the first and third resistors.

16. The system of claim 15, wherein:
the first CMOS switch corresponds to an N-channel metal-oxide semiconductor (NMOS) switch; and
the second CMOS switch corresponds to a P-type metal-oxide-semiconductor logic (PMOS) switch.

17. A method, comprising:
enabling a resistor divider coupled to a first signal driver of a transceiver of an input/output (I/O) component to cause a voltage level of the first signal driver of the I/O component to be decreased to and maintained at a first level while a second signal driver of the transceiver of the I/O component is actively driving a signal; and
enabling one or more resistors coupled to the first signal driver to cause the voltage level of the first signal driver to be increased to a second level at a first rate and maintained at the second level while the first signal driver is actively driving the signal, wherein the second level is higher than the first level.

18. The method of claim 17, wherein:
the resistor divider comprises a first resistor and a second resistor; and
the one or more resistors comprises the first resistor and a third resistor;
wherein the method further comprises enabling, while maintaining the third resistor disabled, the first resistor to cause a voltage level of the first signal driver to be increased to the second level at a second rate and maintained at the second level while the first signal driver is actively driving the signal, wherein the second rate is faster than the first rate.

19. The method of claim 17, wherein:
enabling the resistor divider coupled to the first signal driver further comprises activating a first complementary metal-oxide semiconductor (CMOS) switch coupled to the resistor divider; and
enabling the one or more resistors coupled to the first signal driver further comprises activating a second CMOS switch coupled to the resistor divider.

20. The method of claim 17, further comprising:
disabling the resistor divider coupled to the first signal driver, while the first signal driver is actively driving a signal; and
disabling the one or more resistors coupled to the first signal driver, while the second signal driver is actively driving a signal.
